(19) United States
(12) Patent Application Publication
(10) Pub. No.: US 2011/0121342 A1
(43) Pub. Date: May 26, 2011

(54) ORGANIC LIGHT EMITTING DIODE LIGHTING APPARATUS

(75) Inventors: Hyuk-Sang JUN, Yongin-City (KR); Ok-Keun SONG, Yongin-City (KR); Young-Mo KOO, Yongin-City (KR); Il-Hwa HONG, Yongin-City (KR); Jung-Ha LEE, Yongin-City (KR)

(73) Assignee: SAMSUNG MOBILE DISPLAY CO., LTD., Yongin-City (KR)

(21) Appl. No.: 12/953,572

(22) Filed: Nov. 24, 2010

(30) Foreign Application Priority Data
Nov. 24, 2009 (KR) 10-2009-0114165

(51) Int. Cl. H01L 33/42

(52) U.S. Cl. 257/98; 257/E33.073

(57) ABSTRACT

An organic light emitting diode lighting apparatus includes: a substrate; a semi-transmissive resonance layer formed on the substrate and including multilayer films having different refractive indexes; a first electrode formed on the semi-transmissive resonance layer; a first emission layer formed on the first electrode; a second emission layer formed on the first emission layer and emitting light of a different color from that emitted by the first emission layer; and a second electrode formed on the second emission layer.

### CROSS-REFERENCE TO RELATED APPLICATION

This application claims priority to and the benefit of Korean Patent Application No. 10-2009-0114165 filed in the Korean Intellectual Property Office on Nov. 24, 2009, the entire contents of which are incorporated herein by reference.

### BACKGROUND

(a) Field

The present invention relates to a lighting apparatus. More particularly, the present invention relates to an organic light emitting diode lighting apparatus.

(b) Description of the Related Art

An organic light emitting diode (OLED) has a hole injection electrode, an organic emission layer, and an electron injection electrode. The OLED emits light using energy generated when excitons produced by electron-hole combinations in the organic emission layer drop from an excitation state to a ground state.

An organic light emitting diode lighting apparatus is a lighting apparatus using an organic light emitting diode, and is a surface light source. Thus, the organic light emitting diode lighting apparatus is used for various purposes while retaining the advantages of the surface light source, and the range of applications thereof is gradually expanding.

In general, a lighting apparatus mainly emits white light. An organic light emitting diode lighting apparatus requires various methods for effectively improving the light efficiency of white light.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to solve the problem of the above-mentioned background art and to provide an organic light emitting diode lighting apparatus that is improved in light efficiency.

An organic light emitting diode lighting apparatus according to an exemplary embodiment of the present invention includes: a substrate; a semi-transmissive resonance layer formed on the substrate and including a plurality of layers having different refractive indexes; a first electrode formed on the semi-transmissive resonance layer; a first emission layer formed on the first electrode; a second emission layer formed on the first emission layer and emitting light of a different color from that emitted by the first emission layer; and a second electrode formed on the second emission layer.

Light emitted from the first emission layer and the second emission layer may be mixed to emit white light.

Either of the first emission layer and the second emission layer may emit light in the wavelength range of 550 nm to 620 nm. The other of the first emission layer and the second emission layer may emit light in the wavelength range of 430 nm to 480 nm.

The white light may be warm white having a color temperature of 4,000K or more.

The semi-transmissive resonance layer may include a protective layer and a refractive layer having a higher refractive index than the protective layer.

The protective layer may be made of at least one of silicon oxide (SiO₂), silicon nitride (SiₓN_{y}), and silicon oxy-nitride (SiOₓN_{y}).

The refractive layer may be a semi-transmissive metal layer.

The semi-transmissive layer may have a thickness ranging from 5 nm to 20 nm.

The semi-transmissive metal layer may be made of at least one metal of magnesium (Mg), silver (Ag), gold (Au), calcium (Ca), lithium (Li), chromium (Cr), and aluminum (Al), or an alloy thereof.

The refractive layer may include at least one of TiO₂, Nb₂O₅, Ta₂O₅, ZnO₂, ZrO₂, and SixNy.

The refractive layer may be formed of an organic layer.

The refractive layer may have a refractive index of 1.7 or more.

In the organic light emitting diode lighting apparatus, the first electrode may be made of a transparent conductive material, and the second electrode may be made of a reflective material.

The organic light emitting diode lighting apparatus may further include a first common layer disposed between the first electrode and the first emission layer and a second common layer disposed between the second emission layer and the second electrode.

The first electrode may be a hole injection electrode, and the second electrode may be an electron injection electrode.

The first common layer may include at least one of a hole injection layer and a hole transport layer, and the second common layer may include at least one of an electron transport layer and an electron injection layer.

The first electrode may be an electron injection electrode, and the second electrode may be a hole injection electrode.

The first common layer may include at least one of an electron transport layer and an electron injection layer, and the second common layer may include at least one of a hole injection layer and a hole transport layer.

The organic light emitting diode lighting apparatus may further include an interlayer film disposed between the first emission layer and the second emission layer.

An organic light emitting diode lighting apparatus according to another exemplary embodiment of the present invention includes: a substrate; a semi-transmissive resonance layer including a protective layer formed on the substrate and a semi-transmissive metal layer formed on the protective layer, the semi-transmissive metal layer having a thickness ranging from 5 nm to 20 nm and having a higher refractive index than the protective layer, the semi-transmissive metal layer having a refractive index of 1.7 or more; a first electrode formed on the semi-transmissive metal layer; a first emission layer formed on the first electrode, the first emission layer emitting a first light; a second emission layer formed on the first emission layer, the second emission layer emitting a second light different from the first light, the first light and the second light being mixed to emit white light; a second electrode formed on the second emission layer.

An organic light emitting diode lighting apparatus according to yet another exemplary embodiment of the present invention includes: a substrate; a semi-transmissive resonance layer including a protective layer formed on the substrate and a refractive layer formed on the protective layer, the refractive layer including at least one of an inorganic material and an organic material, the refractive layer having a refractive index of 1.7 or more and a higher refractive index than the protective layer; a first electrode formed on the refractive layer; a first emission layer formed on the first electrode, the first emission layer emitting a first light; a second emission layer formed on the first emission layer, the second emission layer emitting a second light different from the first light, the first light and the second light being mixed to emit white light; a second electrode formed on the second emission layer; a second electrode formed on the second emission layer.

### BRIEF DESCRIPTION OF THE DRAWINGS

FIG. 1 is a layout view of an organic light emitting diode lighting apparatus according to a first exemplary embodiment of the present invention.

FIG. 2 is a partial cross-sectional view of the organic light emitting diode lighting apparatus of FIG. 1.

FIG. 3 is a partial cross-sectional view of an organic light emitting diode lighting apparatus according to a second exemplary embodiment of the present invention.

### DETAILED DESCRIPTION

Hereinafter, exemplary embodiments of the present invention will be described in detail with reference to the accompanying drawings such that those skilled in the art can easily carry out the present invention. As those skilled in the art would realize, the described embodiments may be modified in various different ways, all without departing from the spirit or scope of the present invention.

Among several exemplary embodiments, a first exemplary embodiment will be representatively described, and the other exemplary embodiments will be described only with respect to the components differing from those of the first exemplary embodiment.

To clearly describe the present invention, parts not related to the description are omitted, and like reference numerals designate like components throughout the specification.

In the drawings, the sizes and thicknesses of the components are merely shown for convenience of explanation, and therefore the present invention is not necessarily limited to the illustrations described and shown herein.

In the drawings, the thickness of layers, films, panels, regions, etc., are exaggerated for clarity. In the drawings, the thicknesses of some layers and areas are exaggerated for convenience of explanation. It will be understood that when an element such as a layer, film, region, or substrate is referred to as being “on” another element, it can be directly on the other element or intervening elements may also be present.

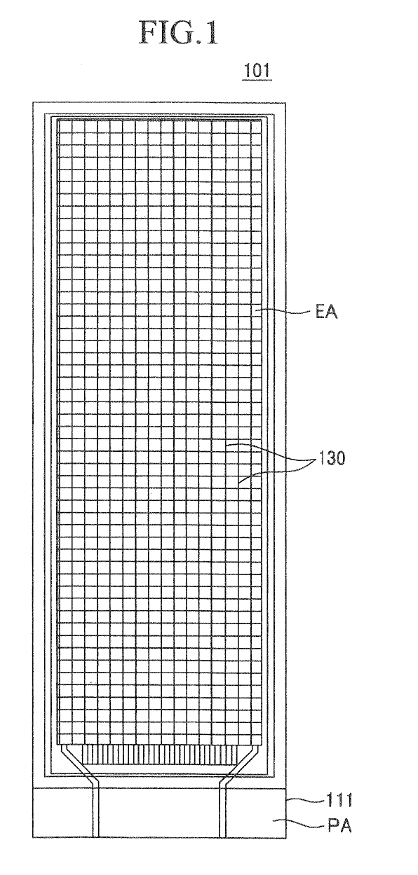

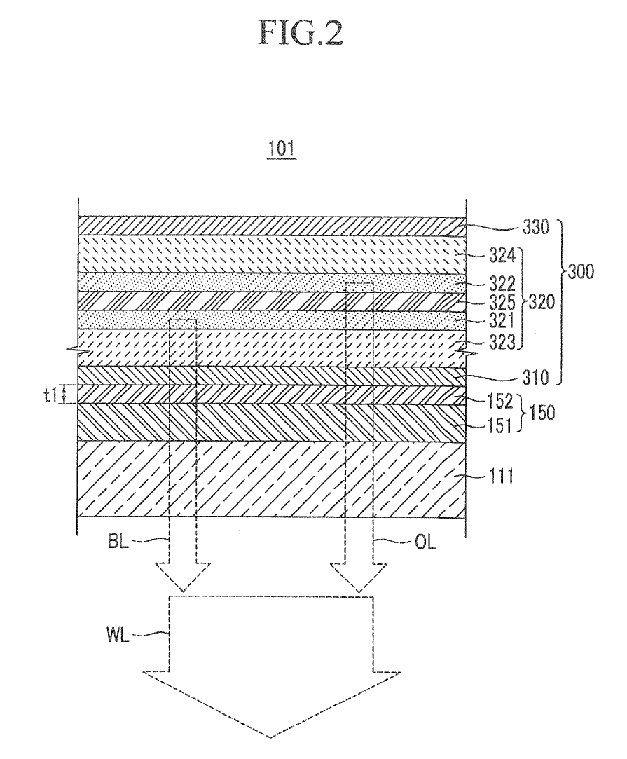

Now, a first exemplary embodiment of the present invention will be described with reference to FIGS. 1 and 2.

As shown in FIGS. 1 and 2, an organic light emitting diode lighting apparatus 101 according to the first exemplary embodiment of the present invention includes a substrate 111, a semi-transmissive resonance layer 150, a first electrode 310, an organic emission layer 320, and a second electrode 330. The first electrode 310, the organic emission layer 320, and the second electrode 330 form an organic light emitting diode (OLED) 300. The organic emission layer 320 includes a first emission layer 321 and a second emission layer 322. The organic emission layer 320 may further include a first common layer 323, a second common layer 324, and an interlayer film 325 as needed.

The substrate 111 is formed of a transparent insulating material. For instance, the substrate 111 may be an insulating substrate made of glass, quartz, ceramic, plastic, or the like. Also, as shown in FIG. 1, the substrate 111 is divided into an emitting area EA and a pad area PA.

As shown in FIG. 2, the semi-transmissive resonance layer 150 is formed on the substrate 111. The semi-transmissive resonance layer 150 includes multilayer films 151 and 152 having different refractive indexes. That is, the semi-transmissive resonance layer 150 is a multilayer structure including a protective layer 151 and a refractive layer 152. Here, the refractive layer 152 has a higher refractive index than the protective layer 151, and has a refractive index of 1.7 or more. Further, the protective layer 151 has transmittance of 95% or more, and a refractive index of 1.0 to 1.5.

The protective layer 151 is made of at least one of silicon oxide (SiO₂), silicon nitride (SixNy), and silicon oxy-nitride (SiOxNy).

In the first exemplary embodiment of the present invention, the refractive layer 152 is a semi-transmissive metal layer (hereinafter, referred to as “semi-transmissive metal layer”). The semi-transmissive metal layer 152 is made of at least one metal of magnesium (Mg), silver (Ag), gold (Au), calcium (Ca), lithium (Li), chromium (Cr), and aluminum (Al), or an alloy thereof. Although a metal layer reflects light, the metal layer can transmit light if it is reduced in thickness to several tens of nanometers. Thus, the thinner the semi-transmissive metal layer 152, the higher the transmittance of light, and vice versa. Moreover, the refractive index of the semi-transmissive metal layer 152 varies according to the transmittance of light.

Therefore, the semi-transmissive metal layer 152 has an appropriate thickness in consideration of the transmittance and refractive index of light. In the first exemplary embodiment of the present invention, the semi-transmissive metal layer 152 has a thickness ranging from 5 nm to 20 nm.

In this way, when the protective layer 151 and the semi-transmissive metal layer 152 are formed together, a part of the light emitted from the first emission layer 321 and the second emission layer 322 transmits through the semi-transmissive resonance layer 150, and the other part thereof is reflected from the semi-transmissive resonance layer 150.

The first electrode 310 is formed on the semi-transmissive resonance layer 150. The first electrode 310 is formed of a transparent conductive material. Examples of the transparent conductive material used as the material of the first electrode 310 include ITO (Indium Tin Oxide), IZO (Indium Zinc Oxide), ZnO (Zinc Oxide), and In₂O₃ (Indium Oxide).

In the first exemplary embodiment of the present invention, the first electrode 310 is a positive (+) electrode serving as a hole injection electrode. The second electrode 330 is a negative (−) electrode serving as an electron injection electrode. However, the first exemplary embodiment of the present invention is not limited thereto. Therefore, the first electrode 310 may serve as an electron injection electrode, and the second electrode 330 may serve as a hole injection electrode.

The first common layer 323 is formed on the first electrode 310. That is, the first common layer 323 is disposed between the first electrode 310 and the first emission layer 321. The first common layer 323 includes at least one of a hole injection layer HIL and a hole transport layer HTL. The first common layer 323 functions to smoothly move holes from the first electrode 310 to the first emission layer 321 and the second emission layer 322. Alternatively, if the first electrode 310 is an electron injection electrode, the first common layer 323 may include at least one of an electron transport layer ETL and an electron injection layer EIL.

The first emission layer 321 is formed on the first common layer 323. The second emission layer 322 is formed on the first emission layer 321. The first emission layer 321 and the second emission layer 322 emit lights OL and BL of different colors. The lights respectively emitted from the first emission layer 321 and the second emission layer 322 are mixed to produce white light WL.

In the first exemplary embodiment of the present invention, the first emission layer 321 emits light BL in the wavelength range of 430 nm to 480 nm, and the second emission layer 322 emits light OL in the wavelength range of 550 nm to 620 nm. Here, the color of the light BL in the wavelength range of 430 nm to 480 nm refers to a blue based color, and the color of the light OL in the wavelength range of 550 nm to 620 nm refers to an orange-yellow based color. However, the first exemplary embodiment of the present invention is not limited thereto, and the color of the light BL emitted from the first emission layer 321 and the color of the light OL emitted from the second emission layer 322 may be switched. Moreover, the colors of the lights from the first emission layer 321 and the second emission layer 322 may be mixed to emit light of various wavelengths within a range where white light WL is produced.

The interlayer film 325 is disposed between the first emission layer 321 and the second emission layer 322. The interlayer film 325 prevents the first emission layer 321 and the second emission layer 322 from being unnecessarily mixed, resulting in deterioration. The interlayer film 325 is made of a mixture of lithium or magnesium and organic material that is used for an electron transfer layer of an OLED device.

The second common layer 324 is formed on the second emission layer 322. That is, the second common 324 is disposed between the second emission layer 322 and the second electrode 330. The second common 324 includes at least one of an electron transport layer ETL and an electron injection layer EIL. The second common layer 324 functions to smoothly move electrons from the second electrode 330 to the first emission layer 321 and the second emission layer 322. Alternatively, if the second electrode 330 is a hole injection electrode, the second common layer 324 may include at least one of a hole injection layer HIL and a hole transport layer HTL.

The second electrode 330 is formed on the second common layer 324. The second electrode 330 is formed of a reflective material. For instance, the second electrode 330 may be made of materials such as lithium (Li), calcium (Ca), lithium-fluoride-calcium (LiF/Ca), lithium-fluoride-aluminum (LiF/Al), aluminum (Al), silver (Ag), magnesium (Mg), and gold (Au).

Moreover, the first emission layer 321 and the second emission layer 322 are formed only in the emitting area EA of the substrate 111, and at least one of the first electrode 310 and the second electrode 320 extends from the emitting area EA of the substrate 111 to the pad area PA thereof. The electrodes 310 and 320 extending to the pad area PA of the substrate 111 are connected to an external power source in the pad area PA.

In addition, although not shown in FIG. 2, the organic light emitting diode lighting apparatus 101 may further include an encapsulating member disposed on the second electrode 330 to protect the organic emission layer 320. At this time, a space between the encapsulating member and the substrate 111 is sealed.

The encapsulating member may be formed as an insulation substrate made of glass, quartz, ceramic, plastic, or the like, or as a metal substrate made of stainless steel or the like.

Moreover, the encapsulating member may be formed of at least one organic or inorganic film, or may be formed of an encapsulating thin film including at least one inorganic film and at least one organic film that are stacked together.

The organic light emitting lighting apparatus 101 may further include an auxiliary electrode or a barrier rib layer. Reference numeral 130 in FIG. 1 represents an auxiliary electrode or a barrier rib layer.

The auxiliary electrode lowers the sheet resistance of the first electrode 310, thus improving the electrical characteristics. Since the first electrode 310 is formed of a transparent conductive material, it has relatively high resistivity. Thus, the auxiliary electrode can effectively make up for the electrical characteristics of the first electrode 310.

The barrier rib layer partitions off the emitting area EA, onto which the organic light emitting diode 300 actually emits light, into a number of cells. In the case where a defect such as a short occurs to one region of the organic light emitting diode lighting apparatus 101, the barrier rib layer prevents such a defect from spreading over the entire area. Moreover, the barrier rib layer may be formed of various insulating films that are well known to those skilled in the art, such as silicon nitride (SiNₓ) and silicon oxide (SiO₂).

Either one or both of the auxiliary electrode and the barrier rib layer may be formed as needed.

With the above-described configuration, the organic light emitting diode lighting apparatus 101 according to the first exemplary embodiment of the present invention can effectively improve light efficiency.

In the first exemplary embodiment of the present invention, the organic light emitting diode lighting apparatus 101 effectively emits white light WL by mixing the blue based light BL emitted from the first emission layer 321 and the orange-yellow based light OL emitted from the second emission layer 322.

Moreover, in the first exemplary embodiment of the present invention, the organic light emitting diode lighting apparatus 101 effectively improves light efficiency by means of the semi-transmissive resonance layer 150. The operational effects of the semi-transmissive resonance layer 150 will be described in detail. A part of the light emitted from the first emission layer 321 and the second emission layer 322 is reflected from the semi-transmissive resonance layer 150. As the semi-transmissive resonance layer 150 has the protective layer 151 and the semi-transmissive metal layer 152, a part of the light emitted from the first emission layer 321 and the second emission layer 322 transmits through the semi-transmissive resonance layer 150 and the other part thereof is reflected from the semi-transmissive resonance layer 150. Also, the light reflected from the semi-transmissive resonance layer 150 is amplified every time the light is repeatedly reflected between the second electrode 330 formed of a reflective material and the semi-transmissive resonance layer 150. Owing to this resonance effect, the organic light emitting diode lighting apparatus 101 can improve light efficiency by effectively amplifying light.

Moreover, the semi-transmissive metal layer 152 has a thickness ranging from 5 nm to 20 nm. If the semi-transmissive metal layer 152 has a thickness of less than 5 nm, the transmittance of light is too high, thereby decreasing the resonance effect. In contrast, if the semi-transmissive metal layer 152 has a thickness greater than 20 nm, the transmittance of light is too low, thereby lowering the light efficiency.

The degree of light amplification by the resonance effect differs depending on wavelength. The orange-yellow based light OL emitted from the second emission layer 322 is amplified to a larger degree than the blue based light BL emitted from the first emission layer 321 due to the resonance effect. Thus, when the lights emitted from the first emission layer 321 and the second emission layer 322 are mixed, light WL of warm white that gives a warm feeling is formed. Here, “warm white” refers to a white color having a color temperature of 4,000K or more. Warm white is usually preferred as a white light for lighting purposes. In this manner, the organic light emitting diode lighting apparatus 101 according to the first exemplary embodiment of the present invention can effectively emit light WL of warm white that is preferred for lighting purposes.

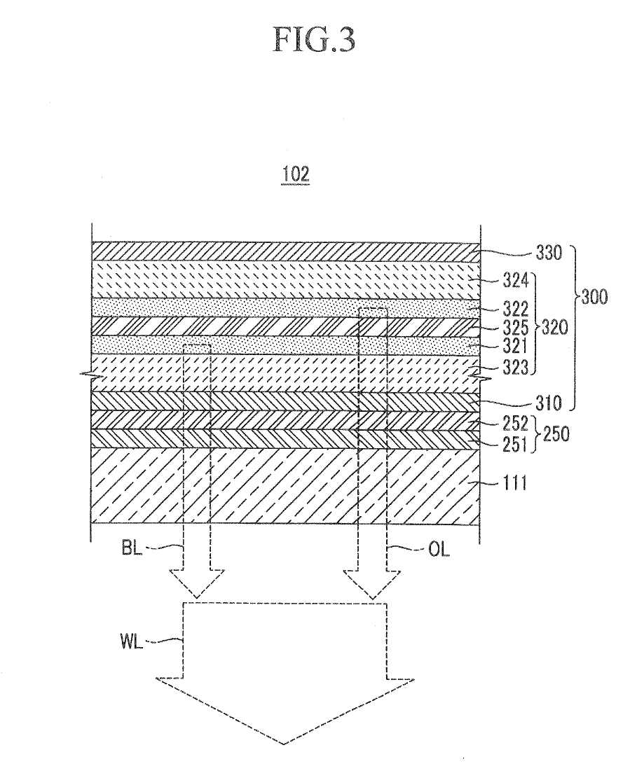

Now, a second exemplary embodiment of the present invention will be described with reference to FIG. 3.

As shown in FIG. 3, in an organic light emitting diode lighting apparatus 102 according to the second exemplary embodiment of the present invention, a refractive layer 252 of a semi-transmissive resonance layer 250 is formed of an inorganic film or an inorganic film. For instance, the inorganic film that can be used as the refractive layer 252 includes at least one of TiO₂, Nb₂O₅, Ta₂O₅, ZnO₂, ZrO₂, and SixNy. Moreover, because the refractive index of the organic film can be easily adjusted depending on its components, most organic films can be used as the refractive layer 252. Here, the refractive layer 252 has a refractive index of 1.7 or more. The protective layer 251 has transmittance of 95% or more, and a refractive index of 1.0 to 1.5.

Further, the protective layer 251 is made of at least one of silicon oxide (SiO₂), silicon nitride (SixNy), and silicon oxy-nitride (SiOxNy), and has a relatively lower refractive index than that of the refractive layer 252.

With the above-described configuration, the organic light emitting diode lighting apparatus 102 according to the second exemplary embodiment of the present invention can effectively improve light efficiency.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode lighting apparatus comprising:
a substrate;
a semi-transmissive resonance layer formed on the substrate, the semi-transmissive resonance layer comprising a plurality of layers having different refractive indexes;
a first electrode formed on the semi-transmissive resonance layer;
a first emission layer formed on the first electrode;
a second emission layer formed on the first emission layer and emitting light of a different color from that emitted by the first emission layer; and
a second electrode formed on the second emission layer.

2. The apparatus of claim 1, wherein lights emitted from the first emission layer and the second emission layer are mixed to emit white light.

3. The apparatus of claim 2, wherein either of the first emission layer and the second emission layer emits light in the wavelength range of 550 nm to 620 nm, and the other of the first emission layer and the second emission layer emits light in the wavelength range of 430 nm to 480 nm.

4. The apparatus of claim 3, wherein the white light is warm white having a color temperature of 4000K or more.

5. The apparatus of claim 2, wherein the semi-transmissive resonance layer comprises a protective layer and a refractive layer having a higher refractive index than a refractive index of the protective layer.

6. The apparatus of claim 5, wherein the protective layer comprises at least one of silicon oxide (SiO₂), silicon nitride (SixNy), and silicon oxy-nitride (SiOxNy).

7. The apparatus of claim 5, wherein the refractive layer is a semi-transmissive metal layer.

8. The apparatus of claim 7, wherein the semi-transmissive layer has a thickness ranging from 5 nm to 20 nm.

9. The apparatus of claim 7, wherein the semi-transmissive metal layer comprises at least one metal of magnesium (Mg), silver (Ag), gold (Au), calcium (Ca), lithium (Li), chromium (Cr), and aluminum (Al), or an alloy thereof.

10. The apparatus of claim 5, wherein the refractive layer comprises at least one of TiO₂, Nb₂O₅, Ta₂O₅, ZnO₂, ZrO₂, and silicon nitride (SiₓN_{y}).

11. The apparatus of claim 5, wherein the refractive layer is formed of an organic layer.

12. The apparatus of claim 5, wherein the refractive layer has a refractive index of 1.7 or more.

13. The apparatus of claim 1, wherein the first electrode is made of a transparent conductive material, and the second electrode is made of a reflective material.

14. The apparatus of claim 13, further comprising a first common layer disposed between the first electrode and the first emission layer, and a second common layer disposed between the second emission layer and the second electrode.

15. The apparatus of claim 14, wherein the first electrode is a hole injection electrode, and the second electrode is an electron injection electrode.

16. The apparatus of claim 15, wherein the first common layer comprises at least one of a hole injection layer and a hole transport layer, and the second common layer comprises at least one of an electron transport layer and an electron injection layer.

17. The apparatus of claim 14, wherein the first electrode is an electron injection electrode, and the second electrode is a hole injection electrode.

18. The apparatus of claim 17, wherein the first common layer comprises at least one of an electron transport layer and an electron injection layer, and the second common layer comprises at least one of a hole injection layer and a hole transport layer.

19. The apparatus of claim 13, further comprising an interlayer film disposed between the first emission layer and the second emission layer.
